(19) United States
(12) Patent Application Publication
(10) Pub. No.: US 2025/0015793 A1
(43) Pub. Date: Jan. 9, 2025

(54) SEMICONDUCTOR DEVICE

(71) Applicant: FUJI ELECTRIC CO., LTD., Kawasaki-shi (JP)

(72) Inventor: Naoki SHIMIZU, Matsumoto-city (JP)

(73) Assignee: FUJI ELECTRIC CO., LTD., Kawasaki-shi (JP)

(21) Appl. No.: 18/678,708

(22) Filed: May 30, 2024

(30) Foreign Application Priority Data
Jul. 5, 2023 (JP) 2023-110989

(51) Int. Cl. H03K 17/082

(52) U.S. Cl. CPC H03K 17/0822

(57) ABSTRACT

A semiconductor device, including: a switch element configured to receive an input signal, and to switch on and off according to the input signal; and a protection control circuit configured to receive an operating state signal from the switch element, and to protect the switch element according to the operating state signal, the operating state signal including one of a short-circuit pulse with a first pulse width, which is generated by the switch element in a short-circuit state, or a micro short-circuit pulse with a second pulse width shorter than the first pulse width, the protection control circuit protecting the switch element upon detecting consecutive occurrences of the micro short-circuit pulse.

### CROSS-REFERENCE TO RELATED APPLICATION

This application is based upon and claims the benefit of priority of the prior Japanese Patent Application No. 2023-110989, filed on Jul. 5, 2023, the entire contents of which are incorporated herein by reference.

### BACKGROUND OF THE INVENTION

### 1. Field of the Invention

The embodiment discussed herein relates to a semiconductor device.

### 2. Background of the Related Art

Semiconductor devices called intelligent power modules (IPMs) have been developed, in which switch elements that are power semiconductors such as insulated gate bipolar transistors (IGBTs), drive circuits for driving the switch elements, and others are built. An IPM is provided with a protection function of protecting switch elements.

As related art, for example, there has been proposed a technique of changing a response time of an overheat protection circuit using an overcurrent detection signal output from an overcurrent protection circuit (see, for example, Japanese Laid-open Patent Publication No. 2002-280886). Further, there has been proposed a technique of determining whether a semiconductor device is in an overheat state, on the basis of a value obtained by adding a voltage corresponding to the temperature of the semiconductor device and a voltage corresponding to a current flowing through the semiconductor device (see, for example, Japanese Laid-open Patent Publication No. 2022-19128). Still further, there has been proposed a technique of lowering a temperature protection level for a switching element as the output current from a power converter increases (see, for example, Japanese Laid-open Patent Publication No. 2007-174832).

### SUMMARY OF THE INVENTION

According to one aspect, there is provided a semiconductor device, including: a switch element configured to receive an input signal, and to switch on and off according to the input signal; and a protection control circuit configured to receive an operating state signal from the switch element, and to protect the switch element according to the operating state signal, the operating state signal including one of a short-circuit pulse with a first pulse width, which is generated by the switch element in a short-circuit state, or a micro short-circuit pulse with a second pulse width shorter than the first pulse width, the protection control circuit protecting the switch element upon detecting consecutive occurrences of the micro short-circuit pulse.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example of a semiconductor device;

FIG. 2 illustrates an example of a state in which the number of consecutive occurrences of a micro short-circuit pulse has reached a predetermined value;

FIG. 3 illustrates an example of a state in which no micro short-circuit pulse has occurred;

FIG. 4 illustrates an example of a state in which the number of consecutive occurrences of the micro short-circuit pulse has not reached the predetermined value;

FIG. 5 illustrates example of the configuration of a semiconductor device;

FIG. 6 is a view for describing protection activated when the number of consecutive occurrences of the micro short-circuit pulse has reached the predetermined value;

FIG. 7 is a view for describing an example of a state in which an IGBT is damaged due to overheating during consecutive occurrences of the micro short-circuit pulse;

FIG. 8 illustrates an example of the configuration of a semiconductor device;

FIG. 9 is a view for describing an operation performed when the time period taken to activate protection is reduced in response to detection of consecutive occurrences of a micro short-circuit pulse and an overheat state;

FIG. 10 illustrates example of the configuration of a semiconductor device;

FIG. 11 illustrates an example of the configuration of a counter circuit;

FIG. 12 illustrates an example of the configuration of a detection delay circuit;

FIG. 13 is a view for describing a detection delay time period; and

FIG. 14 illustrates an example of the configuration of a hysteresis circuit.

### DETAILED DESCRIPTION OF THE INVENTION

Hereinafter, an embodiment will be described with reference to the accompanying drawings. Note that the same reference numerals may be used for elements having substantially the same functions throughout the specification and drawings so as to omit the overlapping description.

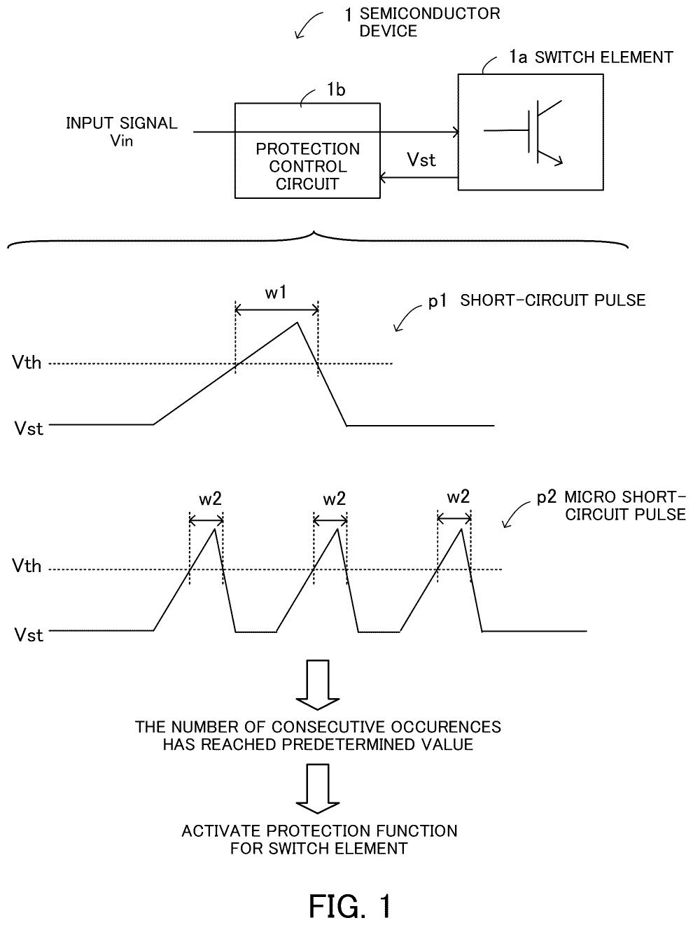

FIG. 1 is a view for describing an example of a semiconductor device. The semiconductor device 1 includes a switch element 1a and a protection control circuit 1b. The switch element 1a switches on and off according to an input signal Vin to drive a load. For example, the switch element 1a is a power semiconductor that is a voltage-driven power control element such as an insulated gate bipolar transistor (IGBT) or a metal-oxide-semiconductor field-effect transistor (MOSFET).

The protection control circuit 1b protects the switch element 1a depending on the voltage level of an operating state signal Vst output from the switch element 1a and the duration of the voltage level. When the switch element 1a is in a short-circuit state, the voltage level of the operating state signal Vst continuously exceeds a predetermined level Vth for a predetermined time period or more.

A waveform of the operating state signal Vst with a pulse width greater than a pulse width w1 (first pulse width) in the short-circuit state is referred to as a short-circuit pulse p1. That is, when detecting the short-circuit pulse p1, the protection control circuit 1b protects the switch element 1a.

In addition, a waveform of the operating state signal Vst with a pulse width w2 (second pulse width) less than the pulse width w1 (first pulse width) is referred to as a micro short-circuit pulse p2. In addition, multiple occurrences of the micro short-circuit pulse p2 within a predetermined time period are referred to as consecutive occurrences. When detecting the consecutive occurrences of the micro short-circuit pulse p2, the protection control circuit 1b protects the switch element 1a as well.

The protection control circuit 1b operates as follows. For example, the protection control circuit 1b detects the micro short-circuit pulse p2 with the pulse width w2 (second pulse width) less than the pulse width w1 (first pulse width) of the short-circuit pulse p1. Here, the short-circuit pulse p1 has a voltage level that continuously exceeds the predetermined level Vth for a predetermined time period when the switch element 1a is in the short-circuit state.

Then, the protection control circuit 1b counts the number of consecutive occurrences of the micro short-circuit pulse p2, and when detecting that the number of consecutive occurrences has reached a predetermined value, protects the switch element 1a. For example, in the case where the predetermined value is set to three, the protection control circuit 1b protects the switch element 1a when the number of consecutive occurrences of the micro short-circuit pulse p2 has reached three.

As described above, the semiconductor device 1 is configured to protect the switch element when consecutive occurrences of the micro short-circuit pulse with the second pulse width less than the first pulse width of the short-circuit pulse are detected. This configuration makes it possible to improve the protection function of protecting the switch element, by detecting the consecutive occurrences of the micro short-circuit pulse, which are not detected in conventional short-circuit detection circuits.

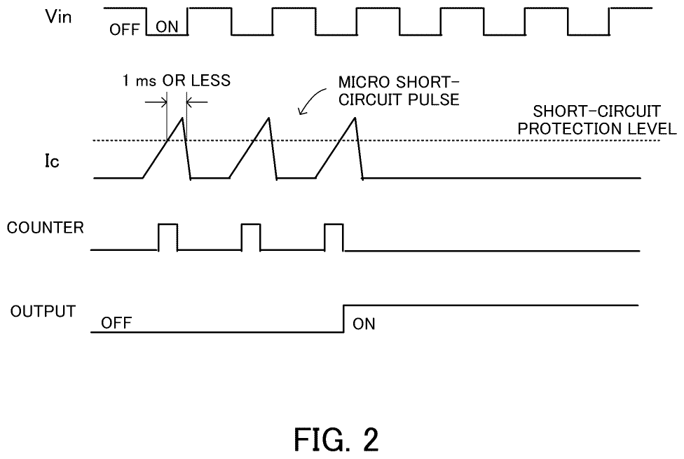

The following describes consecutive occurrences of a micro short-circuit pulse with reference to FIGS. 2 to 4. FIG. 2 illustrates an example of a state in which the number of consecutive occurrences of a short-circuit micro pulse has reached a predetermined value. The switch element 1a is driven on and off according to the on and off of the input signal Vin for driving the switch element 1a. When the switch element 1a is driven on, a collector current Ic flows through the switch element 1a.

Then, when a voltage level that is proportional to the collector current Ic has exceeded a short-circuit protection level (corresponding to the predetermined level Vth of FIG. 1) for a predetermined time period, it is detected that the switch element 1a is in a short-circuit state. The predetermined time period is, for example, 1 ms.

On the other hand, in the case where the time period during which the voltage level has exceeded the short-circuit protection level is less than the predetermined time period, i.e., in the case where a micro short-circuit pulse has occurred, which is a short-circuit pulse with a pulse width less than the short-circuit pulse width that is detected as the normal short-circuit state, the switch element 1a is in a micro short-circuit state.

A counter that the protection control circuit 1b has counts the number of consecutive occurrences of the micro short-circuit pulse. When the number of consecutive occurrences has reached the predetermined value, the protection control circuit 1b outputs a signal for protecting the switch element 1a (in this example, an H-level signal for activating the protection function or an L-level signal for deactivating the protection function).

Assume now that protection for the switch element 1a is activated when the number of consecutive occurrences of the micro short-circuit pulse has reached three. Referring to FIG. 2, the counter has counted to three as the number of consecutive occurrences of the micro short-circuit pulse. Since the number of consecutive occurrences of the micro short-circuit pulse has reached three, an H-level signal is output to protect the switch element 1a.

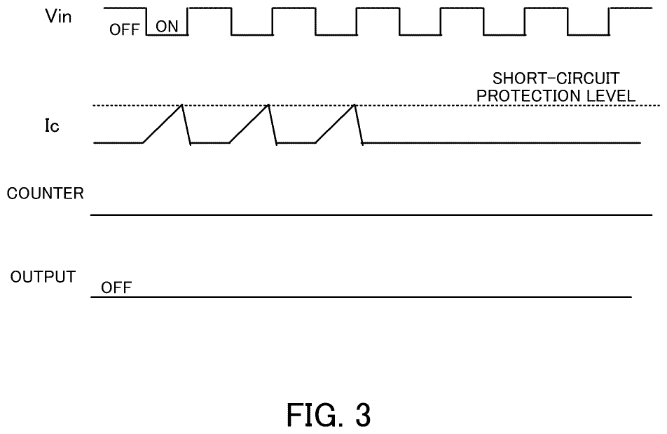

FIG. 3 illustrates an example of a state in which no micro short-circuit pulse has occurred. This state, in which no micro short-circuit pulse has occurred, is a state in which a short circuit has not occurred in the switch element 1a and therefore no short-circuit pulse has occurred. In this case, the counter has not performed the counting operation, so that an L-level signal is output to deactivate the protection function, which is activated according to consecutive occurrences of the micro short-circuit pulse.

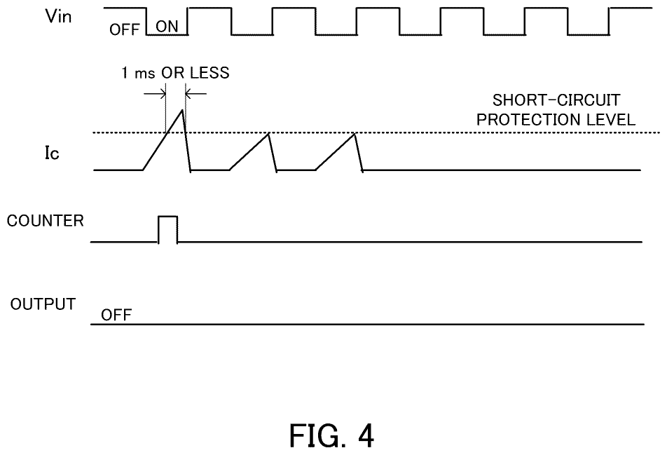

FIG. 4 illustrates an example of a state in which the number of consecutive occurrences of the micro short-circuit pulse has not reached the predetermined value. The micro short-circuit pulse occurred once, but has not occurred since. In this case, the counter has counted to one, but is then reset because the number of consecutive occurrences has not reached the predetermined value. Therefore, an L-level signal is output to deactivate the protection function, which is activated according to consecutive occurrences of the micro short-circuit pulse.

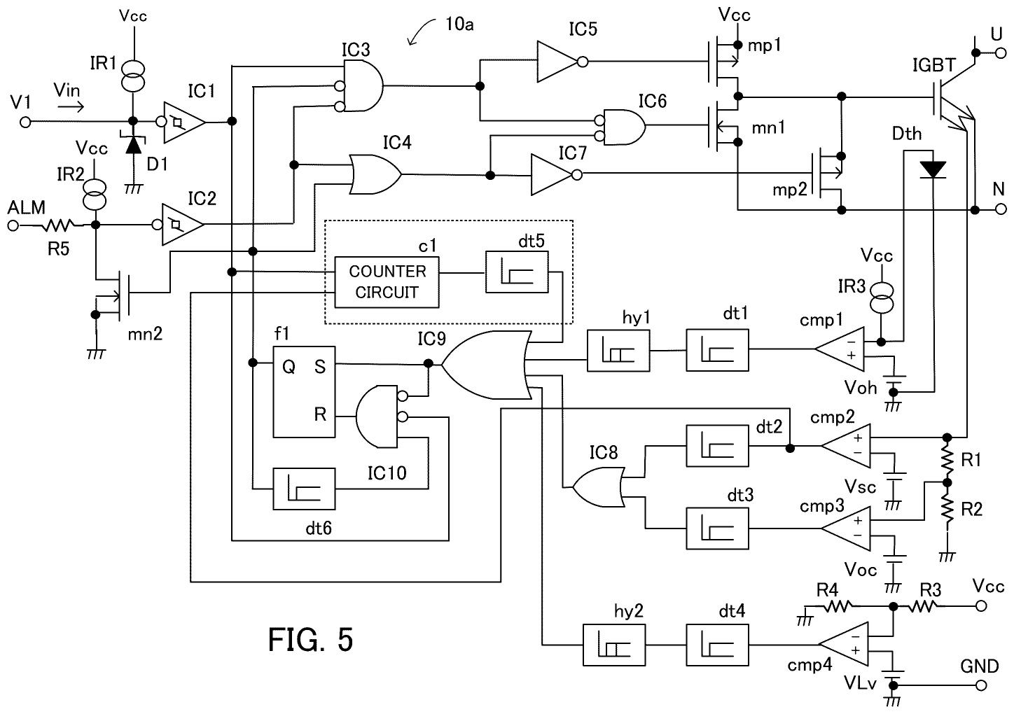

The following describes the configuration and operation of the semiconductor device 1 in detail. FIG. 5 illustrates an example of the configuration of a semiconductor device. The semiconductor device 10a includes an IGBT with a current sensing function and a temperature detection diode Dth for detecting the operating temperature of the IGBT. The IGBT and temperature detection diode Dth are implemented on a single chip.

The semiconductor device 10a further includes, as component elements, constant current sources IR1 to IR3, logic elements IC1 to IC10, p-channel metal oxide semiconductor (PMOS) transistors mp1 and mp2, n-channel metal oxide semiconductor (NMOS) transistors mn1 and mn2, a counter circuit c1, an SR flip-flop f1, detection delay circuits dt1 to dt6, hysteresis circuits hy1 and hy2, comparators cmp1 to cmp4, resistors R1 to R5, and a plurality of reference voltage sources that respectively output reference voltages Voh, Vsc, Voc, and VLv.

In this connection, the detection delay circuits are able to individually set therein a detection delay time period, and are each configured to output a received signal at the elapse of the predetermined time period (at the elapse of the detection delay time period) from the detection of the received signal. The counter circuit c1 and detection delay circuit dt5 illustrated in a dashed box in FIG. 5 correspond to the protection control circuit.

The following describes the connections between the component elements. An input terminal V1 to which the input signal Vin is input is connected to the output terminal of the constant current source IR1, the input terminal of the Schmitt trigger inverter IC1, and the cathode of a Zener diode D1. The input terminal of the constant current source IR1 is connected to a power supply voltage Vcc, and the anode of the Zener diode D1 is connected to the GND.

An alarm output terminal ALM is connected to one end of the resistor R5. The other end of the resistor R5 is connected to the output terminal of the constant current source IR2, the input terminal of the Schmitt trigger inverter IC2, and the drain of the NMOS transistor mn2. The input terminal of the constant current source IR2 is connected to the power supply voltage Vcc, and the source of the NMOS transistor mn2 is connected to the GND.

An output terminal of the Schmitt trigger inverter IC1 is connected to a first input terminal of the 3-input, 1-output logic element IC3, one input terminal of the counter circuit c1, and a first input terminal of the 3-input, 1-output logic element IC10.

The output terminal of the Schmitt trigger inverter IC2 is connected to a second input terminal of the logic element IC3 and one input terminal of the 2-input, 1-output OR element IC4. A third input terminal of the logic element IC3 is connected to the other input terminal of the OR element IC4, the gate of the NMOS transistor mn2, the output terminal Q of the SR flip-flop f1, and the input terminal of the detection delay circuit dt6.

The output terminal of the logic element IC3 is connected to the input terminal of the inverter element IC5 and one input terminal of the 2-input, 1-output logic element IC6. The output terminal of the OR element IC4 is connected to the other input terminal of the logic element IC6 and the input terminal of the inverter element IC7.

The output terminal of the inverter element IC5 is connected to the gate of the PMOS transistor mp1, the output terminal of the logic element IC6 is connected to the gate of the NMOS transistor mn1, and the output terminal of the inverter element IC7 is connected to the gate of the PMOS transistor mp2.

The source of the PMOS transistor mp1 is connected to the power supply voltage Vcc. The drain of the PMOS transistor mp1 is connected to the drain of the NMOS transistor mn1, the source of the PMOS transistor mp2, and the gate of the IGBT. The source of the NMOS transistor mn1 is connected to the drain of the PMOS transistor mp2, the emitter of the IGBT, and an N terminal.

The anode of the temperature detection diode Dth is connected to the output terminal of the constant current source IR3 and the inverting input terminal (−) of the comparator cmp1. The input terminal of the constant current source IR3 is connected to the power supply voltage Vcc. The cathode of the temperature detection diode Dth is connected to the GND.

The collector of the IGBT is connected to a U terminal, and the sense emitter of the IGBT is connected to the non-inverting input terminal (+) of the comparator cmp2 and one end of the resistor R1. The other end of the resistor R1 is connected to one end of the resistor R2 and the non-inverting input terminal (+) of the comparator cmp3. The other end of the resistor R2 is connected to the GND.

One end of the resistor R3 is connected to the power supply terminal Vcc that is configured to apply a power supply voltage Vcc to the device, and the other end of the resistor R3 is connected to one end of the resistor R4 and the inverting input terminal (−) of the comparator cmp4. The other end of the resistor R4 is connected to the GND. The GND terminal is configured to supply the GND to the device.

The non-inverting input terminal (+) of the comparator cmp1 is connected to the positive electrode terminal of the reference voltage source that outputs the reference voltage Voh for overheat detection, and the negative electrode terminal of the reference voltage source is connected to the GND. The inverting input terminal (−) of the comparator cmp2 is connected to the positive electrode terminal of the reference voltage source that outputs the reference voltage Vsc for short-circuit detection, and the negative electrode terminal of the reference voltage source is connected to the GND.

The inverting input terminal (−) of the comparator cmp3 is connected to the positive electrode terminal of the reference voltage source that outputs the reference voltage Voc for overcurrent detection, and the negative electrode terminal of the reference voltage source is connected to the GND. The non-inverting input terminal (+) of the comparator cmp4 is connected to the positive electrode terminal of the reference voltage source that outputs the reference voltage VLv for control voltage drop detection, and the negative electrode terminal of the reference voltage source is connected to the GND.

The output terminal of the counter circuit c1 is connected to the input terminal of the detection delay circuit dt5, and the output terminal of the detection delay circuit dt5 is connected to a first input terminal of the 4-input, 1-output OR element IC9. The output terminal of the comparator cmp1 is connected to the input terminal of the detection delay circuit dt1, the output terminal of the detection delay circuit dt1 is connected to the input terminal of the hysteresis circuit hy1, and the output terminal of the hysteresis circuit hy1 is connected to a second input terminal of the OR element IC9.

The output terminal of the comparator cmp2 is connected to the input terminal of the detection delay circuit dt2 and the other input terminal of the counter circuit c1, and the output terminal of the detection delay circuit dt2 is connected to one input terminal of the 2-input, 1-output OR element IC8.

The output terminal of the comparator cmp3 is connected to the input terminal of the detection delay circuit dt3, and the output terminal of the detection delay circuit dt3 is connected to the other input terminal of the OR element IC8. The output terminal of the OR element IC8 is connected to a third input terminal of the OR element IC9.

The output terminal of the comparator cmp4 is connected to the input terminal of the detection delay circuit dt4, the output terminal of the detection delay circuit dt4 is connected to the input terminal of the hysteresis circuit hy2, and the output terminal of the hysteresis circuit hy2 is connected to a fourth input terminal of the OR element IC9.

The output terminal of the OR element IC9 is connected to the input terminal S (set terminal) of the SR flip-flop f1 and a second input terminal of the logic element IC10. A third input terminal of the logic element IC10 is connected to the output terminal of the detection delay circuit dt6. The output terminal of the logic element IC10 is connected to the input terminal R (reset terminal) of the SR flip-flop f1.

The following describes operation. The comparator cmp1, detection delay circuit dt1, and hysteresis circuit hy1 provide an overheat detection function corresponding to an overheat detection circuit. When a voltage corresponding to the temperature characteristic (negative temperature characteristic) of the IGBT monitored by the temperature detection diode Dth falls below the reference voltage Voh, the comparator cmp1 determines that the IGBT is in an overheat state and then outputs an H-level signal.

When the detection delay circuit dt1 continuously receives the H-level signal output from the comparator cmp1 for the set detection delay time period, the detection delay circuit dt1 outputs the H-level signal at the elapse of the detection delay time period from the reception of the H-level signal. The hysteresis circuit hy1 has hysteresis setting so that, even if the H-level signal output from the detection delay circuit dt1 is affected by short-time changes in temperature, its output level does not change frequently. Thereby, the hysteresis circuit hy1 outputs the H-level signal stably when the overheat state is detected.

The comparator cmp2 and detection delay circuit dt2 provide a short-circuit detection function corresponding to a short-circuit detection circuit. When a voltage corresponding to the sense current of the IGBT increases to the reference voltage Vsc or higher, the comparator cmp2 determines that the IGBT is in a short-circuit state and then outputs an H-level signal. When the detection delay circuit dt2 continuously receives the H-level signal output from the comparator cmp2 for the set detection delay time period, the detection delay circuit dt2 outputs the H-level signal at the elapse of the detection delay time period from the reception of the H-level signal.

The comparator cmp3 and detection delay circuit dt3 provide an overcurrent detection function corresponding to an overcurrent detection circuit. The comparator cmp3 compares a divided voltage obtained by dividing the voltage corresponding to the sense current of the IGBT across the resistors R1 and R2, with the reference voltage Voc. When the divided voltage has reached the reference voltage Voc or higher, the comparator cmp3 determines that the IGBT is in an overcurrent state and then outputs an H-level signal. When the detection delay circuit dt3 continuously receives the H-level signal output from the comparator cmp3 for the set detection delay time period, the detection delay circuit dt3 outputs the H-level signal at the elapse of the detection delay time period from the reception of the H-level signal.

The comparator cmp4, detection delay circuit dt4, and hysteresis circuit hy2 provide a control voltage drop detection function corresponding to a control voltage drop detection circuit. The comparator cmp4 compares a divided voltage obtained by dividing the power supply voltage Vcc across the resistors R3 and R4 with the reference voltage VLv. When the divided voltage falls below the reference voltage VLv, the comparator cmp4 determines that a control voltage is in a drop state and then outputs an H-level signal.

When the detection delay circuit dt4 continuously receives the H-level signal output from the comparator cmp4 for the set detection delay time period, the detection delay circuit dt4 outputs the H-level signal at the elapse of the detection delay time period from the reception of the H-level signal. The hysteresis circuit hy2 has hysteresis setting so that, even if the H-level signal output from the detection delay circuit dt4 is affected by short-time changes in the control voltage, its output level does not change frequently. Thereby, the hysteresis circuit hy2 outputs the H-level signal stably when the control voltage drop state is detected.

Assume now that, in the case where a short-circuit occurs in the IGBT and an H-level signal (detection signal) is therefore output from the comparator cmp2 (comparator for short-circuit detection), the detection delay circuit dt2 (detection delay circuit for short-circuit detection) outputs the H-level signal indicating the short-circuit state (short-circuit detection signal) at the elapse of 1 ms when it continuously receives the H-level signal for 1 ms. Therefore, a micro short-circuit pulse of less than 1 ms is detectable, from the output of the comparator cmp2 before being input to the detection delay circuit dt2.

The counter circuit c1 counts the pulses of the H-level signal (detection signal) output from the comparator cmp2 in synchronization with the input signal Vin output from the Schmitt trigger inverter IC1, thereby counting the number of consecutive occurrences of the micro short-circuit pulse.

In this connection, the counter circuit c1 is configured to perform the counting operation in synchronization with the input signal Vin output from the Schmitt trigger inverter IC1. Alternatively, the counter circuit c1 may be configured to receive the gate voltage of the IGBT, instead of the output of the Schmitt trigger inverter IC1, and to perform the counting operation in synchronization with the gate voltage of the IGBT.

The counter circuit c1 outputs an H-level signal (protection signal) when the number of consecutive occurrences of the micro short-circuit pulse has reached a predetermined value, and the detection delay circuit dt5 outputs the H-level signal at the elapse of the set detection delay time period.

The OR element IC9 outputs an H-level signal when at least one of the following abnormal states is detected: an overheat state, a short-circuit state, an overcurrent state, a control voltage drop state, and a state in which the number of consecutive occurrences of the micro short-circuit pulse has reached the predetermined value. When none of these abnormal states is detected and the device is operating normally, the OR element IC9 outputs an L-level signal.

Here, when an H-level signal is output from the OR element IC9, the logic element IC10 outputs an L-level signal. At this time, the input terminals S and R of the SR flip-flop f1 are at levels of (S, R)=(1, 0), and therefore the SR flip-flop f1 outputs an H-level signal from the output terminal Q.

When the output terminal Q of the SR flip-flop f1 is at H level, this means that at least one of the following abnormal states has occurred: the overheat state, the short-circuit state, the overcurrent state, the control voltage drop state, and the state in which the number of consecutive occurrences of the micro short-circuit pulse has reached the predetermined value.

When the abnormal state is eliminated and an L-level signal is output from the OR element IC9 and the output from the Schmitt trigger inverter IC1 is at L level (when the input signal Vin is at H level to indicate a turn-off instruction), the logic element IC10 outputs an H-level signal to thereby reset the SR flip-flop f1.

At this time, the input terminals S and R of the SR flip-flop f1 are at levels of (S, R)=(0, 1). Therefore, the SR flip-flop f1 outputs an L-level signal from the output terminal Q. The L level at the output terminal Q of the SR flip-flop f1 means that there is no abnormal state occurring and the device is in a normal state.

When the device is in an abnormal state, the output terminal Q of the SR flip-flop f1 goes to H level, which turns the NMOS transistor mn2 on and causes the alarm output terminal ALM to output an L-level signal as an alarm to notify the outside that the device is in the abnormal state. In this connection, when the device is in the abnormal state, the output of the Schmitt trigger inverter IC2 is at H level.

By contrast, when the device is in the normal state, the output terminal Q of the SR flip-flop f1 goes to L level, which turns the NMOS transistor mn2 off and causes the alarm output terminal ALM to output an H-level signal that is not an alarm. In this connection, when the device is in the normal state, the output of the Schmitt trigger inverter IC2 is at L level.

When an L-level input signal Vin (a turn-on instruction to turn the IGBT on) is input to the input terminal V1 while the device is in the normal state, the output of the logic element IC3 goes to H level, and the output of the inverter element IC5 goes to L level, which turns the PMOS transistor mp1 on.

Since the output of the OR element IC4 goes to L level, the output of the logic element IC6 goes to L level, which turns the NMOS transistor mn1 off. Since the output of the inverter element IC7 goes to H level, the PMOS transistor mp2 is turned off. Therefore, a signal whose level corresponds to a driving level is input to the gate of the IGBT, so as to turn the IGBT on.

In addition, when an H-level input signal Vin (a turn-off instruction to turn the IGBT off) is input to the input terminal V1 while the device is in the normal state, the output of the logic element IC3 goes to L level, and the output of the inverter element IC5 goes to H level, which turns the PMOS transistor mp1 off. Since the output of the OR element IC4 goes to L level, the output of the logic element IC6 goes to H level, which turns the NMOS transistor mn1 on. Since the output of the inverter element IC7 goes to H level, the PMOS transistor mp2 is turned off. Therefore, the gate of the IGBT goes to a level corresponding to the turn-off instruction, so as to turn the IGBT off.

Furthermore, when the device is in an abnormal state, the output of the OR element IC4 goes to H level, and the output of the inverter element IC7 goes to L level, which turns the PMOS transistor mp2 on. This causes charges to be drawn from the gate of the IGBT, so that the IGBT is forcibly turned off to protect the IGBT during the abnormal state.

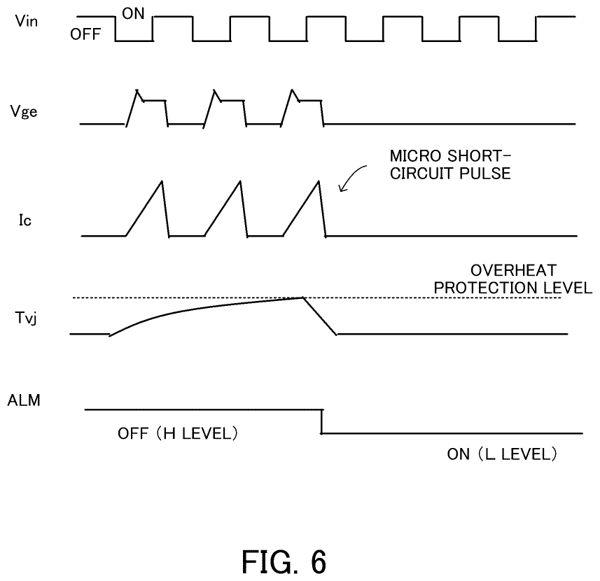

FIG. 6 is a view for describing protection activated when the number of consecutive occurrences of the micro short-circuit pulse has reached the predetermined value. Assume that the protection for the IGBT is activated when the number of consecutive occurrences of the micro short-circuit pulse has reached three. In the example of FIG. 6, the operating temperature Tvj of the IGBT does not exceed an overheat protection level. However, at the time point when the number of consecutive occurrences of the micro short-circuit pulse has reached three, an L-level alarm signal ALM indicating an abnormality is output. In addition, at the time point when the number of consecutive occurrences of the micro short-circuit pulse has reached three, the gate voltage Vge goes to L level, which turns the IGBT off to protect the IGBT.

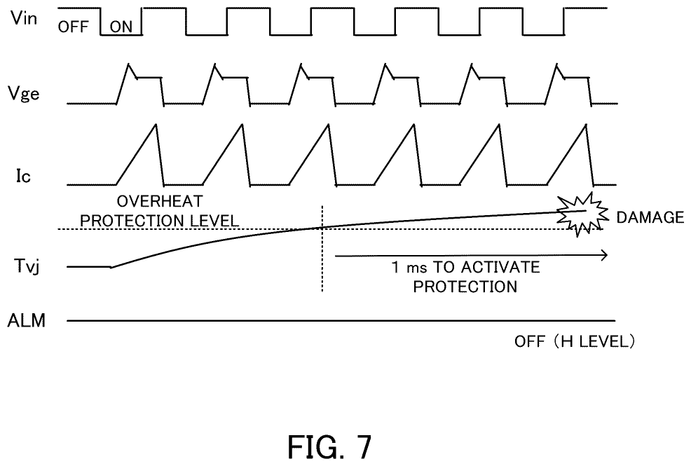

The following describes protection of the IGBT that is performed when consecutive occurrences of a micro short-circuit pulse and an overheat state are detected. FIG. 7 is a view for describing an example of a state in which an IGBT is damaged due to overheating during consecutive occurrences of the micro short-circuit pulse.

Assume now that the overheat protection is activated when the overheat protection level is exceeded for 1 ms or more. There is a possibility that if a micro short-circuit pulse occurs consecutively during this time period, the operating temperature of the IGBT may increase due to the occurrences of the micro short-circuit pulse before the overheat protection is activated by the overheat detection function, and the IGBT may be damaged before being protected. In other words, if it takes 1 ms from the detection of an overheat state to the activation of the protection, there is a risk that the IGBT may be damaged due to a temperature rise caused by the occurrences of the micro short-circuit pulse before 1 ms elapses.

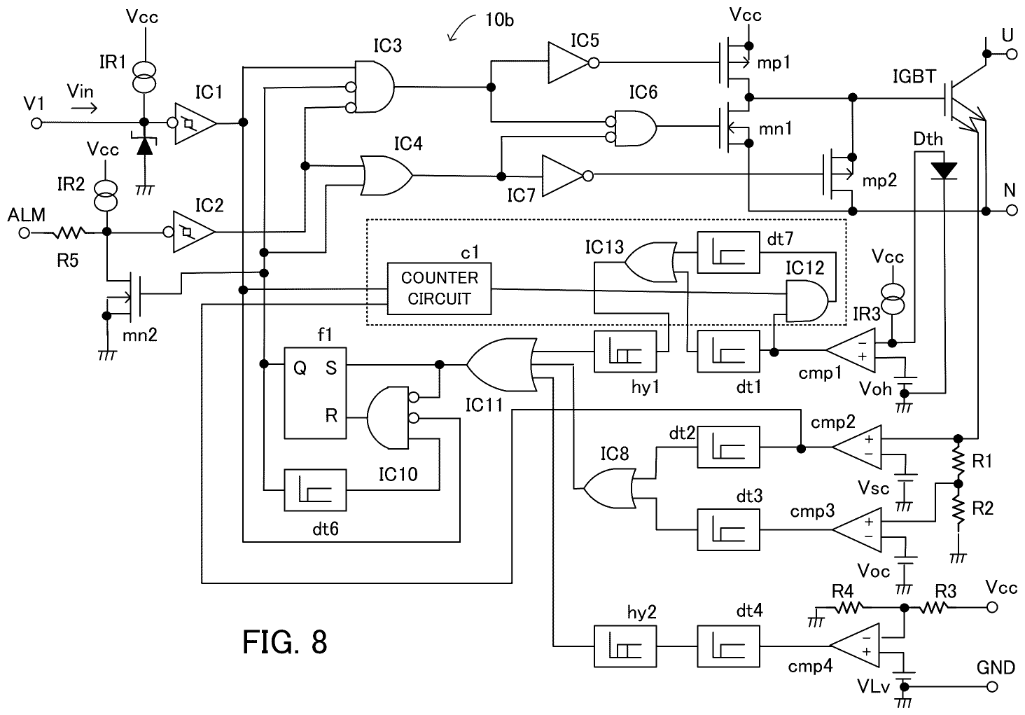

FIG. 8 illustrates an example of the configuration of a semiconductor device. The semiconductor device 10b is a circuit that is designed to prevent damage in an IGBT by reducing an operation time period that is taken to activate overheat protection when a micro short-circuit pulse occurs consecutively.

The semiconductor device 10b includes, as a protection control circuit, a counter circuit c1, a 2-input, 1-output AND element IC12, a detection delay circuit dt7 (detection delay circuit for time reduction), and a 2-input, 1-output OR element IC13, as illustrated in a dashed box in FIG. 8. In addition, the OR element IC9 illustrated in FIG. 5 is replaced with a 3-input, 1-output OR element IC11. The rest of the circuit configuration is the same as in FIG. 5.

Here, as described earlier, the counter circuit c1 counts the pulses of an H-level signal (first detection signal) output from the comparator cmp2 in synchronization with the input signal Vin, which is output from the Schmitt trigger inverter IC1, thereby counting the number of consecutive occurrences of the micro short-circuit pulse.

The counter circuit c1 outputs an H-level signal (counter signal) when the number of consecutive occurrences of the micro short-circuit pulse has reached a predetermined value. In addition, when a voltage corresponding to the operating temperature of the IGBT falls below the reference voltage Voh, the comparator cmp1 (comparator for overheat detection) determines that the IGBT is in an overheat state and then outputs an H-level signal (second detection signal).

Therefore, the AND element IC12 outputs an H-level signal (AND signal) to the detection delay circuit dt7 when the number of consecutive occurrences of the micro short-circuit pulse has reached the predetermined value and the IGBT is in the overheat state.

When the detection delay circuit dt7 (detection delay circuit for time reduction) continuously receives the H-level signal output from the AND element IC12 for the set detection delay time period, it outputs the H-level signal at the elapse of the detection delay time period.

In this case, the detection delay circuit dt7 has set therein the detection delay time period (second time period) shorter than the detection delay time period (first time period) of the detection delay circuit dt1 (detection delay circuit for overheat detection). For example, in the case where the detection delay time period (first time period) of the detection delay circuit dt1 is 1 ms, the detection delay time period (second time period) of 10 us is set in the detection delay circuit dt7.

Therefore, the detection delay circuit dt1 outputs an H-level signal (overheat detection signal) at the elapse of the detection delay time period of 1 ms from the detection of the overheat state. The detection delay circuit outputs an H-level signal (time reduction detection signal) at the elapse of 10 us from the detection of the overheat state, when the number of consecutive occurrences of the micro short-circuit pulse has reached the predetermined value and the IGBT is detected to be in an overheat state.

When the OR element IC13 receives at least one of the H-level signal (overheat detection signal) output from the detection delay circuit dt1 and the H-level signal (time reduction detection signal) output from the detection delay circuit dt7, the OR element IC13 outputs an H-level signal (protection signal) to the hysteresis circuit hy1.

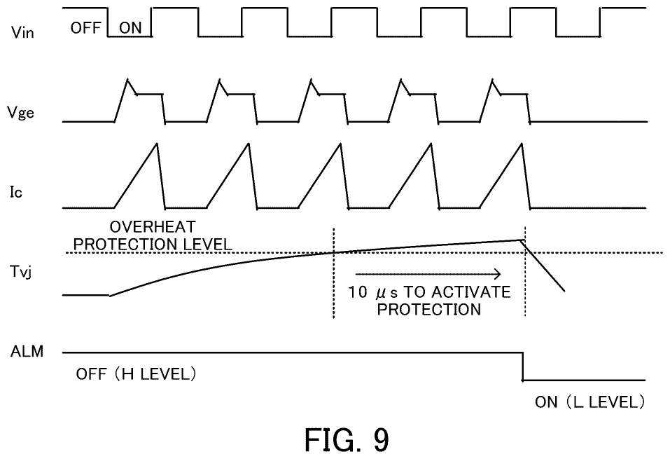

FIG. 9 is a view for describing an operation performed when the time period taken to activate protection is reduced in response to detection of consecutive occurrences of a micro short-circuit pulse and an overheat state. Assume that the number of times for detecting the consecutive occurrences of the micro short-circuit pulse is set to three. When the number of consecutive occurrences of the micro short-circuit pulse has reached three and the operating temperature Tvj of the IGBT has exceeded an overheat protection level, the time period taken to activate overheat protection is reduced to 10 μs.

Therefore, when 10 us has elapsed from the detection of the overheat state, an L-level alarm signal ALM indicating an abnormality is output. In addition, the gate voltage Vge goes to L level, which forcibly turns the IGBT off to protect the IGBT.

As described above, when the consecutive occurrences of the micro short-circuit pulse and the overheat state are detected, the time period taken to output a protection signal, which is set for activating the normal overheat protection, is reduced (for example, reduced from 1 ms to 10 μs). This makes it possible to activate the protection before the IGBT goes into the overheat state that may lead to damaging the IGBT. As a result, the damage in the IGBT is prevented.

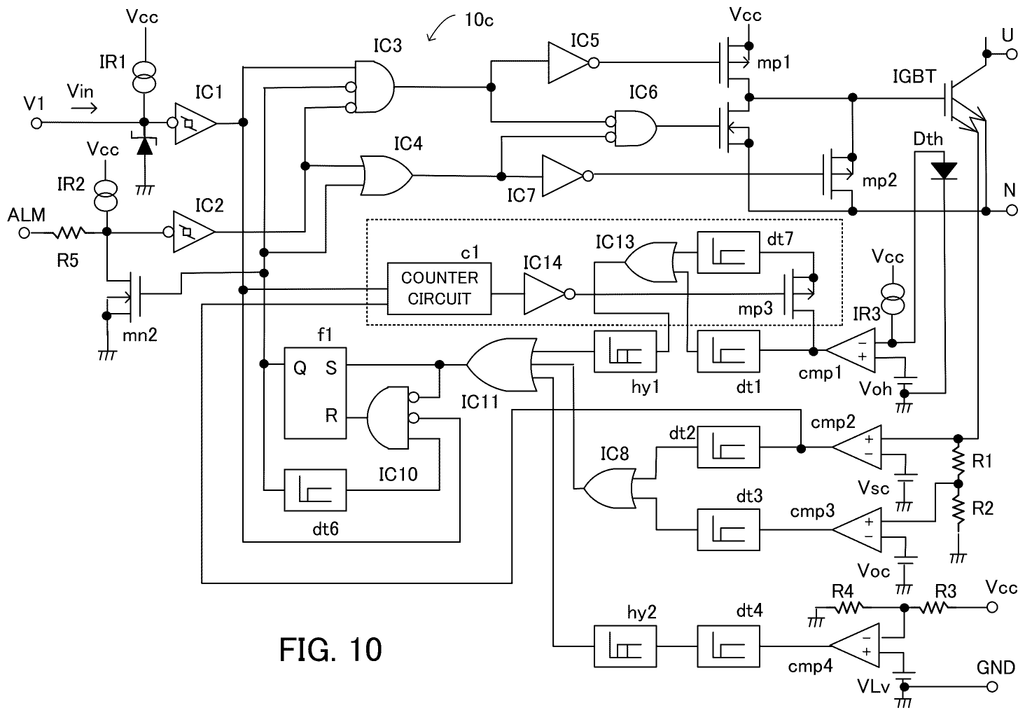

FIG. 10 illustrates an example of the configuration of a semiconductor device. The semiconductor device 10c is a modification of the semiconductor device 10b illustrated in FIG. 8. The semiconductor device 10c includes, as the protection control circuit, a counter circuit c1, an inverter element IC14, a PMOS transistor mp3, a detection delay circuit dt7 (detection delay circuit for time reduction), and an OR element IC13, as illustrated in a dashed box in FIG. 10. In the semiconductor device 10c, the AND element IC12 illustrated in FIG. 8 is replaced with the PMOS transistor mp3, and the inverter element IC14 is additionally provided. The rest of the circuit configuration is the same as in FIG. 8.

The counter circuit c1 outputs an H-level signal when the number of consecutive occurrences of the micro short-circuit pulse has reached a predetermined value. The inverter element IC14 inverts the H-level signal and outputs an L-level signal (inverted counter signal). When a voltage corresponding to the operating temperature of the IGBT falls below a reference voltage Voh, the comparator cmp1 determines that the IGBT is in an overheat state and then outputs an H-level signal (second detection signal).

The L-level signal from the inverter element IC14 turns the PMOS transistor mp3 on, so that the H-level signal from the comparator cmp1 is input to the detection delay circuit dt7. The subsequent operation is the same as that of FIG. 8.

Even with the above configuration, when consecutive occurrences of the micro short-circuit pulse and an overheat state are detected, the time period taken to output a protection signal, which is set for activating the normal overheat protection, is reduced (for example, reduced from 1 ms to 10 μs). This makes it possible to activate the protection before the IGBT goes into an overheat state that may lead to damaging the IGBT. As a result, the damage in the IGBT is prevented.

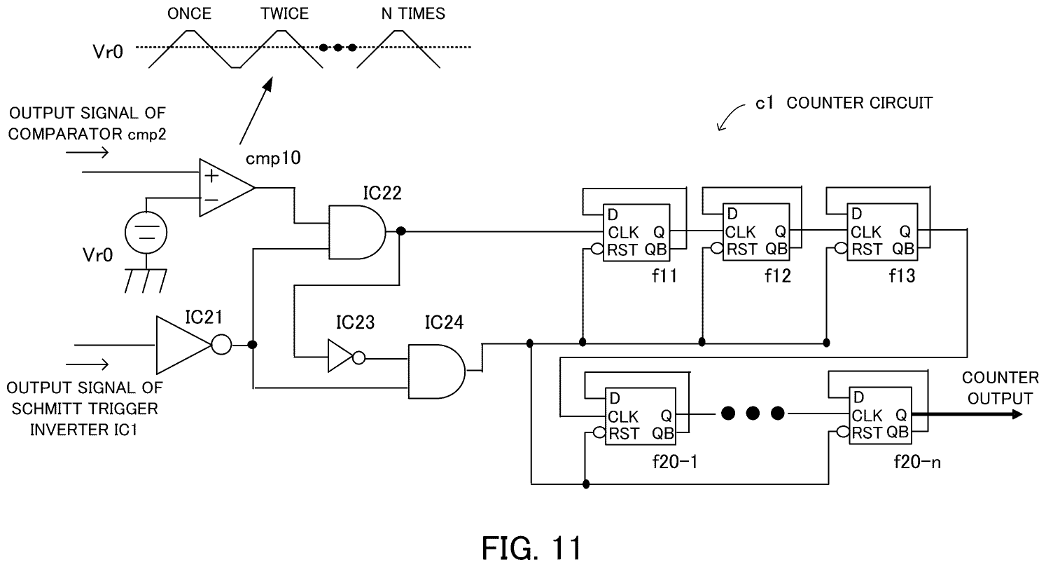

The following describes an example of the configuration of a counter circuit, detection delay circuit, and hysteresis circuit. FIG. 11 illustrates an example of the configuration of a counter circuit. The counter circuit c1 is designed to count occurrences of a pulse (micro short-circuit pulse) with a level exceeding a reference voltage Vr0, and includes a comparator cmp10, a reference voltage source that outputs the reference voltage Vr0, logic elements IC21 to IC24, and D-type flip-flops f11, f12, f13, f20-1, . . . and f20-n.

The input terminal of the inverter element IC21 is connected to the output terminal of the Schmitt trigger inverter IC1, and the output terminal of the inverter element IC21 is connected to one input terminal of the 2-input, 1-output AND element IC22 and one input terminal of the 2-input, 1-output AND element IC24.

The non-inverting input terminal (+) of the comparator cmp10 is connected to the output terminal of the comparator cmp2, and the inverting input terminal (−) of the comparator cmp10 is connected to the positive electrode terminal of the reference voltage source that outputs the reference voltage Vr0. The negative electrode terminal of the reference voltage source is connected to the GND.

The output terminal of the comparator cmp10 is connected to the other input terminal of the AND element IC22. The output terminal of the AND element IC22 is connected to the input terminal of the inverter element IC23 and the clock input terminal CLK of the flip-flop f11. The output terminal of the inverter element IC23 is connected to the other input terminal of the AND element IC24.

The input terminal D of the flip-flop f11 is connected to the inverting output terminal QB of the flip-flop f11. The input terminal D of the flip-flop f12 is connected to the inverting output terminal QB of the flip-flop f12, and the input terminal D of the flip-flop f13 is connected to the inverting output terminal QB of the flip-flop f13.

The output terminal Q of the flip-flop f11 is connected to the clock input terminal CLK of the flip-flop f12, and the output terminal Q of the flip-flop f12 is connected to the clock input terminal CLK of the flip-flop f13.

The input terminal D of the flip-flop f20-1 is connected to the inverting output terminal QB of the flip-flop f20-1, and the input terminal D of the flip-flop f20-n is connected to the inverting output terminal QB of the flip-flop f20-n. The output terminal Q of the flip-flop f20-1 is connected to the clock input terminal CLK of a flip-flop provided after the flip-flop f20-1, and the clock input terminal CLK of the flip-flop f20-n is connected to the output terminal Q of a flip-flop provided before the flip-flop f20-n.

The output terminal of the AND element IC24 is connected to the reset input terminal RST of each of the flip-flops f11, f12, and f13 and also to the reset input terminal RST of each of the flip-flops f20-1, and f20-n.

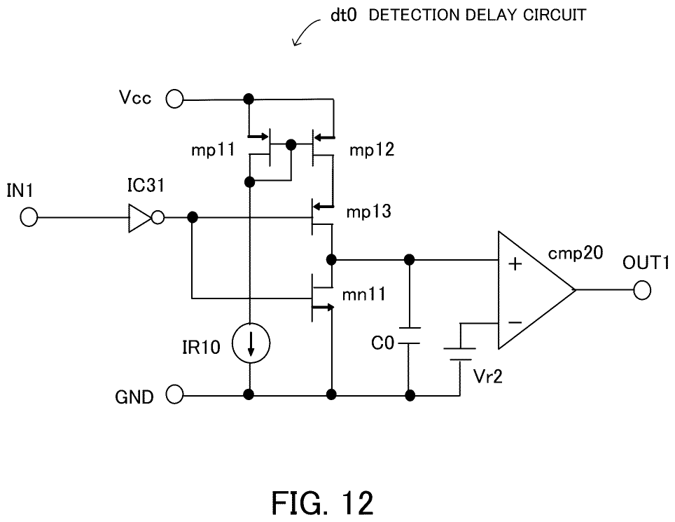

FIG. 12 illustrates an example of the configuration of a detection delay circuit. The detection delay circuit dt0 includes an inverter element IC31, a constant current source IR10, PMOS transistors mp11, mp12, and mp13, an NMOS transistor mn11, a capacitor C0, a reference voltage source that outputs a reference voltage Vr2, and a comparator cmp20.

An input terminal IN1 is connected to the input terminal of the inverter element IC31, and the output terminal of the inverter element IC31 is connected to the gate of the PMOS transistor mp13 and the gate of the NMOS transistor mn11.

A power supply terminal Vcc is connected to the source of the PMOS transistor mp11 and the source of the PMOS transistor mp12. The gate of the PMOS transistor mp11 is connected to the drain of the PMOS transistor mp11, the gate of the PMOS transistor mp12, and the input terminal of the constant current source IR10.

The drain of the PMOS transistor mp12 is connected to the source of the PMOS transistor mp13. The drain of the PMOS transistor mp13 is connected to the drain of the NMOS transistor mn11, one end of the capacitor C0, and the non-inverting input terminal (+) of the comparator cmp20. The inverting input terminal (−) of the comparator cmp20 is connected to the positive electrode terminal of the reference voltage source that outputs the reference voltage Vr2.

The GND terminal is connected to the output terminal of the constant current source IR10, the source of the NMOS transistor mn11, the other end of the capacitor C0, and the negative electrode terminal of the reference voltage source that outputs the reference voltage Vr2. The output terminal of the comparator cmp20 is connected to an output terminal OUT1.

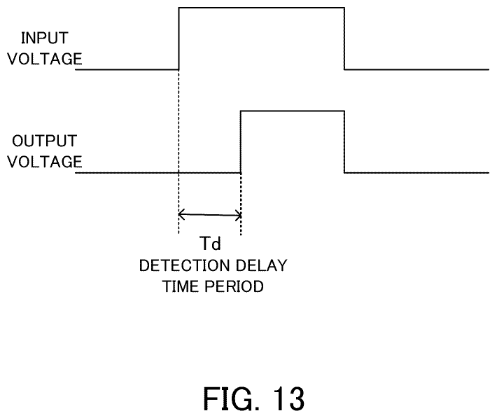

FIG. 13 is a view for describing a detection delay time period. Assume now that an H-level voltage is supplied to the input terminal IN1 of the detection delay circuit dt0. When the detection delay circuit dt0 continuously receives the H level for the detection delay time period Td, the detection delay circuit dt0 outputs the H-level voltage from the output terminal OUT1 thereof at the elapse of the detection delay time period Td.

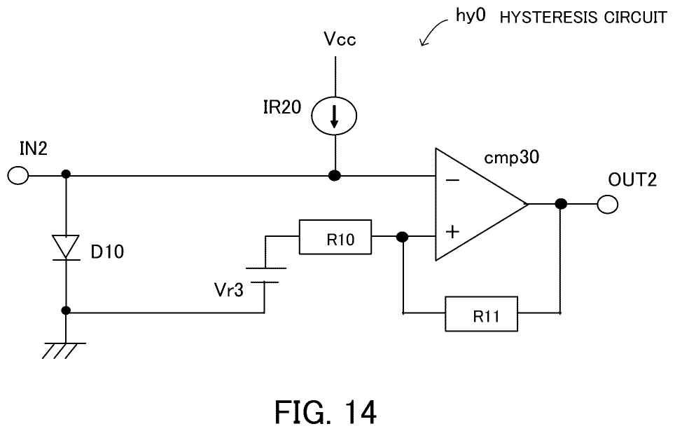

FIG. 14 illustrates an example of the configuration of a hysteresis circuit. The hysteresis circuit hy0 includes a constant current source IR20, a diode D10, a reference voltage source that outputs a reference voltage Vr3, resistors R10 and R11, and a comparator cmp30.

An input terminal IN2 is connected to the anode of the diode D10, the output terminal of the constant current source IR20, and the inverting input terminal (−) of the comparator cmp30. The input terminal of the constant current source IR20 is connected to the power supply voltage Vcc.

The cathode of the diode D10 is connected to the negative electrode terminal of the reference voltage source that outputs the reference voltage Vr3 and the GND. The positive electrode terminal of the reference voltage source that outputs the reference voltage Vr3 is connected to one end of the resistor R10, and the other end of the resistor R10 is connected to the non-inverting input terminal (+) of the comparator cmp30 and one end of the resistor R11. The output terminal of the comparator cmp30 is connected to the other end of the resistor R11 and an output terminal OUT2.

Heretofore, the embodiment has been described. Each component in the embodiment may be replaced with another component having an equivalent function. In addition, other desired configurations and steps may be added. Furthermore, two or more desired configurations (features) in the embodiment described above may be combined.

According to one aspect, it is possible to improve a protection function of protecting a switch element, by detecting consecutive occurrences of a micro short-circuit pulse.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a switch element configured to receive an input signal, and to switch on and off according to the input signal; and
a protection control circuit configured to receive an operating state signal from the switch element, and to protect the switch element according to the operating state signal, the operating state signal including one of
a short-circuit pulse with a first pulse width, which is generated by the switch element in a short-circuit state, or
a micro short-circuit pulse with a second pulse width shorter than the first pulse width, the protection control circuit protecting the switch element upon detecting consecutive occurrences of the micro short-circuit pulse.

2. The semiconductor device according to claim 1, further comprising a short-circuit detection circuit configured to detect the short-circuit state of the switch element and output a short-circuit detection signal,
wherein the protection control circuit detects the consecutive occurrences of the micro short-circuit pulse.

3. The semiconductor device according to claim 2, wherein
the short-circuit detection circuit includes
a comparator for short-circuit detection, configured to output a detection signal upon detecting the short-circuit state of the switch element, and
a detection delay circuit for short-circuit detection, configured to receive the detection signal for a predetermined time period and output the short-circuit detection signal at an elapse of the predetermined time period, and
the protection control circuit includes a counter circuit configured to
detect the consecutive occurrences of the micro short-circuit pulse from the detection signal,
count a number of the consecutive occurrences the micro short-circuit pulse in of synchronization with the input signal, and
output a protection signal in response to the number of the consecutive occurrences reaching a predetermined value.

4. The semiconductor device according to claim 3, wherein the protection control circuit outputs the protection signal, to thereby cause the switch element to switch off, and an alarm to be outputted by the semiconductor device.

5. The semiconductor device according to claim 3, wherein
the predetermined time period is 1 ms, and
the second pulse width is less than 1 ms.

6. The semiconductor device according to claim 2, further comprising an overheat detection circuit configured to
detect an operating temperature of the switch element, and
output an overheat detection signal upon determining that the switch element is in an overheat state for a first time period, wherein
the short-circuit detection circuit outputs the short-circuit detection signal upon detecting the short-circuit pulse, and
the protection control circuit
detects the consecutive occurrences of the micro short-circuit pulse, and
outputs a protection signal at an elapse of a second time period in response to both a number of the consecutive occurrences of the micro short-circuit pulse reaching a predetermined value and the output of the overheat detection signal, the second time period being shorter than the first time period, wherein
the short-circuit pulse continuously exceeds a predetermined level for a predetermined time period, and
the micro short-circuit pulse continuously exceeds the predetermined level for less than the predetermined time period, and is not detectable by the short-circuit detection circuit.

7. The semiconductor device according to claim 6, wherein
the short-circuit detection circuit includes
a comparator for short-circuit detection, configured to output a first detection signal upon detecting the short-circuit state of the switch element, and
a detection delay circuit for short-circuit detection, configured to receive the first detection signal for the predetermined time period and output the short-circuit detection signal at an elapse of the predetermined time period, and the overheat detection circuit includes
a comparator for overheat detection, configured to output a second detection signal upon detecting the overheat state of the switch element, and
a detection delay circuit for overheat detection, configured to receive the second detection signal for the first time period and output the overheat detection signal at an elapse of the first time period.

8. The semiconductor device according to claim 7, wherein
the protection control circuit includes a counter circuit, an AND element, a detection delay circuit for time reduction, and an OR element,
the counter circuit is configured to
detect the consecutive occurrences of the micro short-circuit pulse from the first detection signal,
count the number of the consecutive occurrences of the micro short-circuit pulse in synchronization with the input signal, and
output a counter signal in response to the number of the consecutive occurrences reaching the predetermined value,
the AND element is configured to output an AND signal upon receiving the counter signal and the second detection signal,
the detection delay circuit for time reduction is configured to output a time reduction detection signal at an elapse of the second time period from reception of the AND signal, and
the OR element is configured to output the protection signal upon receiving at least one of the overheat detection signal or the time reduction detection signal.

9. The semiconductor device according to claim 7, wherein
the protection control circuit includes a counter circuit, an inverter element, a p-channel metal oxide semiconductor (PMOS) transistor, a detection delay circuit for time reduction, and an OR element,
the counter circuit is configured to
detect the consecutive occurrences of the micro short-circuit pulse from the first detection signal,
count the number of the consecutive occurrences of the micro short-circuit pulse in synchronization with the input signal, and
output a counter signal in response to the number of the consecutive occurrences reaching the predetermined value,
the inverter element is configured to output an inverted counter signal obtained by inverting a level of the counter signal,
the PMOS transistor is configured to be turned on by the inverted counter signal and input the second detection signal to the detection delay circuit for time reduction,
the detection delay circuit for time reduction is configured to output a time reduction detection signal at an elapse of the second time period from reception of the second detection signal, and
the OR element is configured to output the protection signal upon receiving at least one of the overheat detection signal or the time reduction detection signal.

10. The semiconductor device according to claim 6, wherein the protection control circuit outputs the protection signal, to thereby cause the switch element to switch off, and an alarm to be outputted by the semiconductor device.

11. The semiconductor device according to claim 6, wherein
the predetermined time period is 1 ms,
the second pulse width is less than 1 ms,
the first time period is 1 ms, and
the second time period is 10 μs.
